(19) United States
(12) Patent Application Publication
(10) Pub. No.: US 2025/0063860 A1
(43) Pub. Date: Feb. 20, 2025

(54) LIGHT EMITTING DIODE

(71) Applicant: Taiwan-Asia Semiconductor Corporation, Hsinchu City (TW)

(72) Inventors: Hong-Ta CHENG, Hsinchu City (TW); Ching-Yuan TSAI, Hsinchu City (TW); Yao-Hong HUANG, Hsinchu City (TW)

(21) Appl. No.: 18/497,525

(22) Filed: Oct. 30, 2023

(30) Foreign Application Priority Data
Aug. 16, 2023 (TW) 112130771

(51) Int. Cl. H01L 33/42; H01L 33/00; H01L 33/22

(52) U.S. Cl. CPC H01L 33/42; H01L 33/0025; H01L 33/22

(57) ABSTRACT

The present invention relates to a light-emitting diode (LED) which includes an epitaxial composite layer, a dielectric layer, a transparent conductive layer, and a metal layer. Specifically, the epitaxial composite layer is disposed on the dielectric layer, the dielectric layer is disposed on the transparent conductive layer, and the transparent conductive layer is disposed on the metal layer. Moreover, an outer edge of the transparent conductive layer is covered by the metal layer.

### CROSS-REFERENCES TO RELATED APPLICATIONS

This application claims the benefit of priority to Taiwanese Patent Application No. 112130771 filed on Aug. 16, 2023, which is hereby incorporated by reference in its entirety.

### BACKGROUND OF THE INVENTION

### Field of the Invention

The present invention relates to a light emitting diode, in particular a light emitting diode with high brightness.

### Descriptions of the Related Art

Light Emitting Diodes hereinafter referred to as LEDs have advantages of high brightness, small size, low power consumption, and long lifespan. They are widely used in lighting and display products. In the case of quaternary red LEDs with a general wavelength ranging from 590 nanometers (nm) to 1000 nanometers, gallium arsenide (GaAs) epitaxial growth substrates are used therein. For short-wavelength infrared (SWIR) LEDs with a wavelength ranging from 1000 nm to 2000 nm, indium phosphide (InP) epitaxial growth substrates are used therein. In the later stage of the manufacturing process, to enhance the optoelectronic performance of LEDs, a metal bonding process is carried out with another permanent bonding substrate. After bonding to the permanent substrate, the original epitaxial growth substrate would be removed. For quaternary red GaAs-based substrates, ammonia solution is commonly used to remove the GaAs substrate. On the other hand, when indium phosphide is used as the epitaxial growth substrate, hydrochloric acid solution is used for the substrate removal. However, during the removal of the indium phosphide epitaxial growth substrate, the transparent conductive film in the LED structure is susceptible to erosion and damage on the outer edges by the hydrochloric acid solution. Therefore, the yield rate of the manufacturing process is reduced accordingly.

To overcome the aforementioned issues, an innovative LED structure and its manufacturing process are needed to solve the problem of defect loss caused by erosion and damage to the outer edges of the transparent conductive film during the removal of the epitaxial growth substrate using hydrochloric acid and to enhance the brightness of LEDs.

### SUMMARY OF THE INVENTION

The main objective of the present invention is to provide a light-emitting diode with an innovative transparent conductive layer structure, so as to overcome the problem caused by susceptibility to corroded and damaged the transparent conductive layer in the conventional light emitting diode structure by hydrochloric acid solution. Thus, the brightness of the light emitting diode and the yield rate of manufacturing the same will be improved accordingly.

To achieve the above objective, the present invention discloses a light emitting diode (LED) which includes an epitaxial composite layer, a dielectric layer, a transparent conductive layer, and a metal layer. Specifically, the epitaxial composite layer is disposed on the dielectric layer, the dielectric layer is disposed on the transparent conductive layer, and the transparent conductive layer is disposed on the metal layer. Moreover, an outer edge of the transparent conductive layer is covered by the metal layer.

In one embodiment of the light emitting diode of the present invention, the transparent conductive layer further includes a plurality of dotted transparent electrodes and each of the dotted transparent electrodes is surrounded by the dielectric layer.

In one embodiment of the light emitting diode of the present invention, the material of the transparent conductive layer is one of a group consisting of indium tin oxide, aluminum zinc oxide, tin zinc oxide, zinc oxide, nickel oxide, cadmium tin oxide, antimony tin oxide and a combination thereof.

In one embodiment of the light emitting diode of the present invention, an outer edge of the dielectric layer is covered by the metal layer.

In one embodiment of the light emitting diode of the present invention, the epitaxial composite layer further includes a first semiconductor layer, a light emitting layer, a second semiconductor layer, and a third semiconductor layer. The third semiconductor layers is disposed on the dielectric layer and electrically connected to the transparent conductive layer, the second semiconductor layer is disposed on the third semiconductor layer, the light emitting layer is disposed on the second semiconductor layer, and the first semiconductor layer is disposed on the light emitting layer.

In one embodiment of the light emitting diode of the present invention, the first semiconductor layer is an N-type indium phosphide epitaxial layer, the second semiconductor layer is a P-type indium phosphide epitaxial layer, and the third semiconductor layer is a P-type indium gallium arsenide epitaxial layer.

In one embodiment of the light emitting diode of the present invention, the wavelength of the light emitting layer is ranging from 1000 nanometers to 2000 nanometers.

In one embodiment of the light emitting diode of the present invention, the light emitting diode further includes an upper electrode disposed on the epitaxial composite layer without overlapping the dotted transparent electrodes.

In one embodiment of the light emitting diode of the present invention, the material of the metal layer is one of gold (Au), silver (Ag), aluminum (Al), beryllium gold (BeAu), germanium gold (GeAu), and a combination thereof.

In one embodiment of the light emitting diode of the present invention, the light emitting diode further includes a substrate connected to the metal layer.

The detailed technology and preferred embodiments implemented for the present invention are described in the following paragraphs accompanying the appended drawings for people skilled in this field to well appreciate the features of the claimed invention.

### BRIEF DESCRIPTION OF THE DRAWINGS

FIG. 1 to FIG. 8 are schematic views of the structure and manufacturing process of a light emitting diode according to one embodiment of the present invention; and

FIG. 5A and FIG. 8A are schematic views of the structure and manufacturing process of a light emitting diode according to another embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

Reference is made to FIG. 1 which schematically illustrates the manufacturing process of a light emitting diode in one embodiment of the present invention. Particularly, a short-wavelength infrared light emitting diode (LED) using indium phosphide (InP) as an epitaxial growth substrate 100 is used as an example but not limited thereto. Subsequently, an epitaxial composite layer 105 is formed on the indium phosphide substrate. Specifically, in this embodiment, the epitaxial composite layer 105 includes an N-type first semiconductor layer 110, a light emitting layer 120, a second semiconductor layer 130, and a third semiconductor layer 140. The first semiconductor layer 110 is disposed on the epitaxial growth substrate 100. The light emitting layer 120 is disposed on the first semiconductor layer 110. The second semiconductor layer 130 is disposed on the light emitting layer 120. The third semiconductor layer 140 is disposed on the second semiconductor layer 130. The light emitting layer 120 is formed as a multiple quantum well (MQW) structure, and in this embodiment, the wavelength of the MQW structure in the light emitting layer 120 ranges from 1000 to 2000 nanometers. The first semiconductor layer 110 is an N-type indium phosphide (InP) epitaxial layer. The second semiconductor layer 130 is a P-type indium phosphide epitaxial layer. The third semiconductor layer 140 is a P-type indium gallium arsenide (InGaAs) epitaxial layer. It shall be noted that the materials described in the above embodiment are merely exemplary, and the present invention is not limited thereto. In practical applications, the material and composition adjustments can be made according to the wavelength needed, for instance, the epitaxial layer could be aluminum gallium indium phosphide (AlGaInP), indium gallium phosphide (InGaP), aluminum gallium arsenide (AlGaAs), etc.

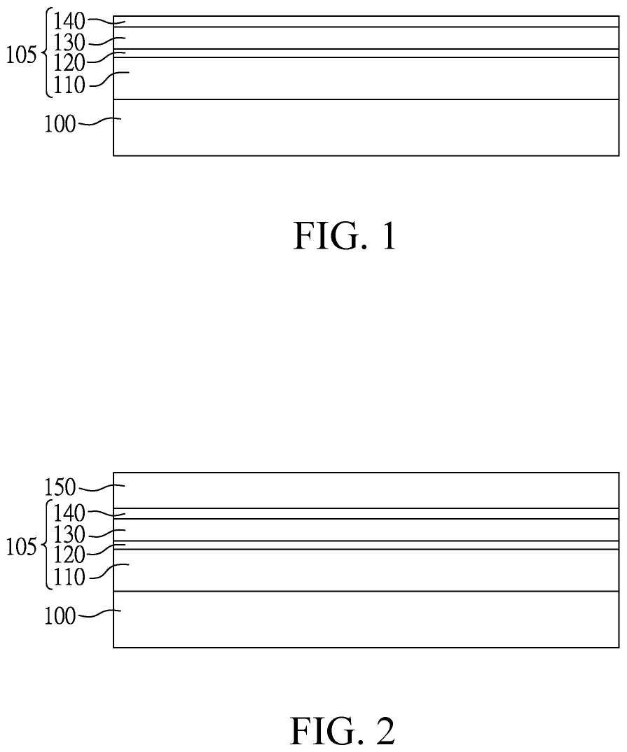

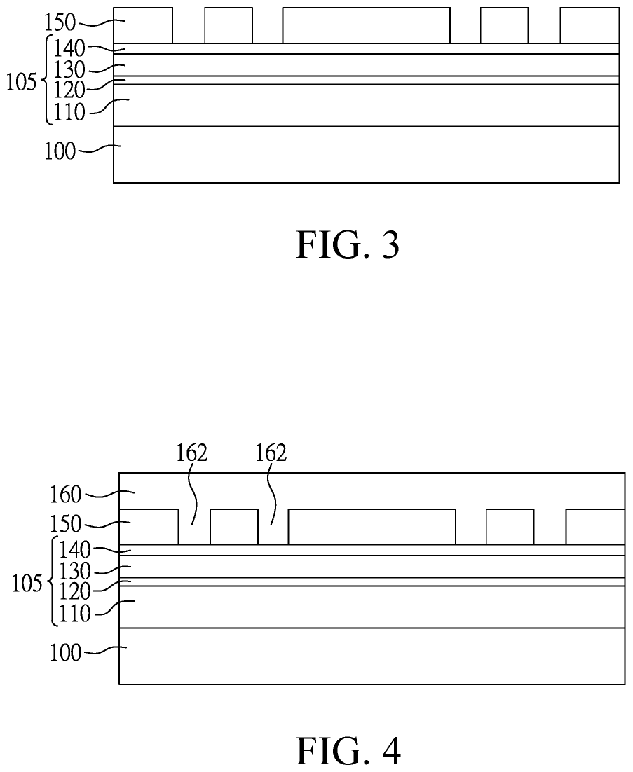

Please refer to FIG. 2, where a dielectric layer 150 is formed to cover the entire epitaxial composite layer 105 by using a chemical vapor deposition method. The dielectric layer 150 is a low-refractive-index dielectric layer, and its material can be silicon oxide (SiOx), silicon nitride (Si3N4), etc. Next, please refer to FIG. 3, where a photolithography process is used to remove a portion of the dielectric layer 150 until the surface of the third semiconductor layer 140 of the epitaxial composite layer 105 is exposed. Thus, a patterned dielectric layer 150 is formed to define the distribution positions and areas of the lower electrodes made next. As shown in FIG. 4, a transparent conductive material is deposited by using an evaporation process to cover the patterned dielectric layer 150 and a transparent conductive layer 160 is formed to cover the exposed epitaxial composite layer 105 and dielectric layer 150. In FIG. 3, the patterned dielectric layer 150 exposes the recessed areas of the epitaxial composite layer 105. After filling the transparent conductive material therein, the recessed areas will form a plurality of dotted transparent electrodes 162. Each dotted transparent electrode 162 is surrounded by the dielectric layer 150, and is electrically connected to the third semiconductor layer 140 and the transparent conductive layer 160, as shown in FIG. 4. In one preferred embodiment, the materials to form the transparent conductive layer 160 and the dotted transparent electrodes 162 are one of indium tin oxide (ITO), aluminum-doped zinc oxide (AZO), indium zinc oxide (IZO), zinc oxide (ZNO), nickel oxide, cadmium tin oxide, antimony tin oxide, and combinations thereof.

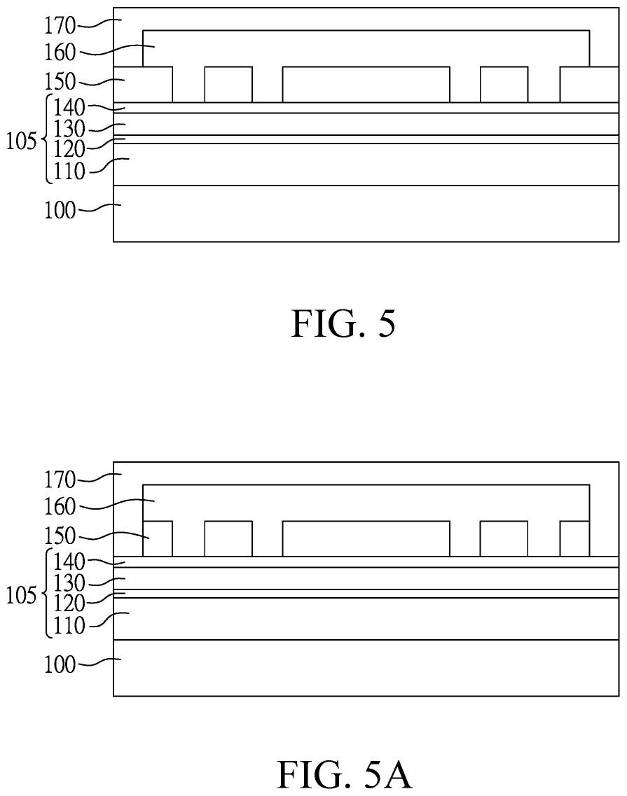

Please refer to FIG. 5, where a photolithography process is used to remove the outer edge portion of the transparent conductive layer 160. Then, a metal layer 170 is formed to cover the entire transparent conductive layer 160 and its outer edge portion by using an evaporation process. The material used to form the metal layer 170 can be one of gold (Au), silver (Ag), aluminum (Al), beryllium gold (BeAu), germanium gold (GeAu), and combinations thereof. Please refer to FIG. 6, where a metal bonding process is performed between the metal layer 170 and a bonding substrate 180. The bonding substrate 180 can be, but not limited to, a silicon substrate or a sapphire substrate.

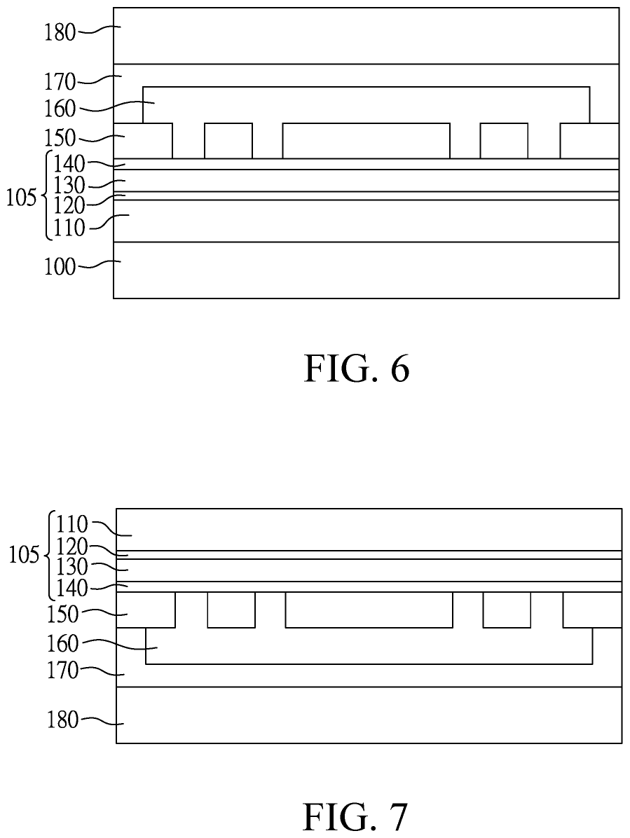

Please refer to FIG. 7, where hydrochloric acid solution is used to remove the indium phosphide epitaxial growth substrate 100 to expose the first semiconductor layer 110 of the epitaxial composite layer 105. The structure is then flipped so the bonding substrate 180 will be relocated at the bottom of the LED structure. It is noted that, by referring together with FIG. 5, since the outer edge of the transparent conductive layer 160 in the LED structure of the present invention is covered by the metal layer 170, the transparent conductive layer 160 is effectively protected from erosion by the hydrochloric acid solution during the removal of the indium phosphide epitaxial growth substrate 100. Thus, the yield rate of the manufacturing process will be increased.

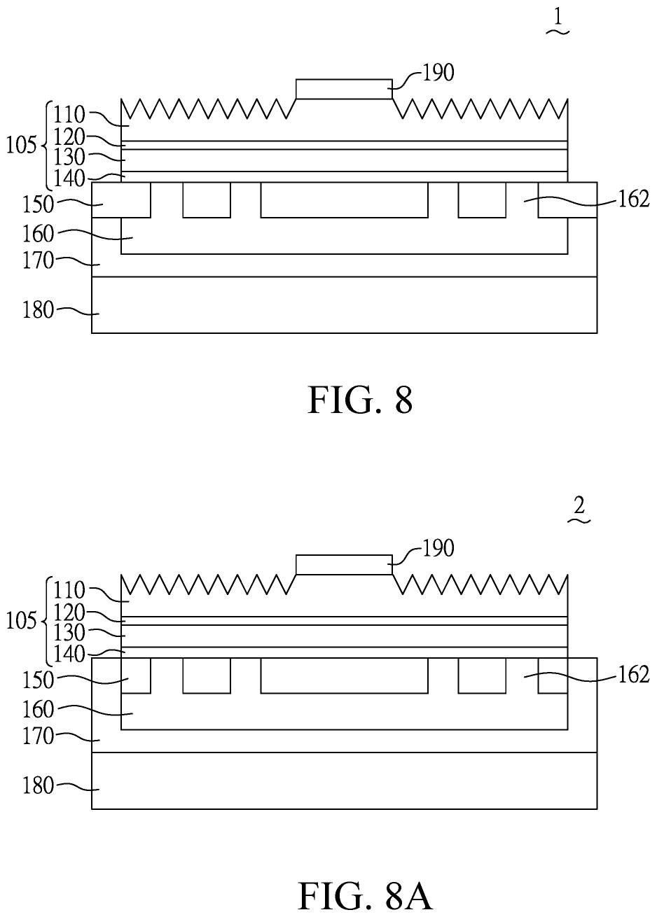

Subsequently, the first semiconductor layer 110 is subjected to a roughening treatment, and the entire epitaxial composite layer 105 undergoes a MESA process. Ultimately, an upper electrode 190 is formed on the first semiconductor layer 110. The final structure of light emitting diode 1 of the present invention is formed, as shown in FIG. 8. The material of the upper electrode 190 can be one of germanium gold (GeAu), germanium gold nickel (GeAuNi), and combination thereof. Additionally, to achieve the effects of current spreading and to prevent light shielding, the upper electrode 190 disposed on the epitaxial composite layer does not vertically overlap with the dotted transparent electrodes 162.

Another embodiment of the present invention will be described below. Please refer to the aforementioned FIG. 1 to FIG. 4 and FIG. 5A together. It is noted that in the early stage of the manufacturing processes of this embodiment is the same as the above-mentioned embodiment, FIGS. 2-5 along with corresponding descriptions can be consolidated for reference and comparison. Further details are not described here. The difference between this embodiment and the previous embodiment is that, not only the outer edge of the transparent conductive layer 160 is removed by the photolithography process, but also the outer edge of the dielectric layer 150 is removed by etching simultaneously, as shown in FIG. 5A. Next, the metal layer 170 is formed to cover the entire transparent conductive layer 160, the dielectric layer 150 and the outer edges thereof by an evaporation process. Other subsequent processes of this embodiment, such as removing the indium phosphide epitaxial growth substrate 100, roughening the first semiconductor layer 110, MESA process, and forming the upper electrode 190, etc. are the same as the above embodiments. Accordingly, please refer to the aforementioned descriptions and the drawings. Further details are not described here.

Please refer to FIG. 8A which shows the final structure of another light emitting diode 2 in this embodiment. Different from the aforementioned embodiments, in this embodiment, the metal layer 170 covers not only the outer edge of the transparent conductive layer 160, but also the outer edge of the transparent conductive layer 160 and the outer edge of the dielectric layer 150. Therefore, when the indium phosphide epitaxial growth substrate 100 is subsequently removed by using hydrochloric acid, the transparent conductive layer 160 and the dielectric layer 150 can be completely protected by the metal layer 170 from being corroded by the hydrochloric acid solution. Therefore, process yield is improved. In addition, in this embodiment, since the metal layer 170 presents a “U” shape, it completely covers the transparent conductive layer 160 and the dielectric layer 150. Compared with the previous embodiment, the “U” shaped metal layer 170 in this embodiment can increase the chance of the light emitted from the light emitting layer to be reflected upwards, so as to improve the light extraction efficiency and brightness thereof.

[symbol] 1 [symbol] It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode, comprising:
an epitaxial composite layer;
a dielectric layer, the epitaxial composite layer being disposed on the dielectric layer;
a transparent conductive layer, the dielectric layer being disposed on the transparent conductive layer; and
a metal layer;
wherein the transparent conductive layer is disposed on the metal layer, and an outer edge of the transparent conductive layer is covered by the metal layer.

2. The light emitting diode of claim 1, wherein the transparent conductive layer further comprises a plurality of dotted transparent electrodes, each of the dotted transparent electrodes is surrounded by the dielectric layer.

3. The light emitting diode of claim 1, wherein a material of the transparent conductive layer is one of indium tin oxide, aluminum zinc oxide, tin zinc oxide, zinc oxide, nickel oxide, cadmium tin oxide, antimony tin oxide and a combination thereof.

4. The light emitting diode of claim 1, wherein the outer edge of the dielectric layer is covered by the metal layer.

5. The light emitting diode of claim 1, wherein the epitaxial composite layer further comprises a first semiconductor layer, a light emitting layer, a second semiconductor layer, and a third semiconductor layer, wherein the third semiconductor layers is disposed on the dielectric layer and electrically connected to the transparent conductive layer, the second semiconductor layer is disposed on the third semiconductor layer, and wherein the light emitting layer is disposed on the second semiconductor layer, and the first semiconductor layer is disposed on the light emitting layer.

6. The light emitting diode of claim 5, wherein the first semiconductor layer is an N-type indium phosphide (InP) epitaxial layer, the second semiconductor layer is a P-type indium phosphide epitaxial layer, and the third semiconductor layer is a P-type indium gallium arsenide (InGaAs) epitaxial layer.

7. The light emitting diode of claim 5, wherein a wavelength of the light emitting layer is ranging from 1000 nanometers (nm) to 2000 nm.

8. The light emitting diode of claim 2, further comprising an upper electrode disposed on the epitaxial composite layer without overlapping the dotted transparent electrodes.

9. The light emitting diode of claim 1, wherein a material of the metal layer is one of gold (Au), silver (Ag), aluminum (Al), beryllium gold (BeAu), germanium gold (GeAu), and a combination thereof.

10. The light emitting diode of claim 1, further comprising a substrate bonding with the metal layer.
